(19) United States
(12) Patent Application Publication
(10) Pub. No.: US 2025/0091860 A1
(43) Pub. Date: Mar. 20, 2025

(54) COMPOUND SENSOR AND MANUFACTURING METHOD

(71) Applicant: Panasonic Intellectual Property Management Co., Ltd., Osaka (JP)

(72) Inventors: Hiroki SAKAMOTO, Fukui (JP); Soichiro HIRAOKA, Hyogo (JP); Hideaki NISHIWAKI, Fukui (JP); Ritsu NAKAYOSHI, Fukui (JP); Natsuki MIYASHITA, Ishikawa (JP); Kouhei YAMADA, Fukui (JP)

(21) Appl. No.: 18/628,262

(22) Filed: Apr. 5, 2024

(30) Foreign Application Priority Data
Sep. 14, 2023 (JP) 2023-149447

(51) Int. Cl. B81B 7/04; B81C 1/00; G01P 1/02

(52) U.S. Cl. CPC B81B 7/04; B81C 1/00214; G01P 1/023; G01P 1/026; B81B 2201/0235; B81B 2201/0242; B81B 2207/053; B81C 2201/0181; B81C 2201/019

(57) ABSTRACT

A compound sensor includes a package, a first acceleration detector, a second acceleration detector, and an angular velocity detector. The first acceleration detector is disposed in a first cavity. The second acceleration detector is disposed in a second cavity. The angular velocity detector is disposed in a third cavity. An inner pressure of the first cavity is higher than an inner pressure of the second cavity. An inner pressure of the third cavity is lower than the inner pressure of the second cavity.

### CROSS-REFERENCE TO RELATED APPLICATION

This application is based on and claims the benefit of foreign priority to Japanese Patent Application No. 2023-149447 filed on Sep. 14, 2023, the entire disclosures of which are hereby incorporated by reference.

### TECHNICAL FIELD

The present disclosure generally relates to compound sensors and manufacturing methods and specifically relates to a compound sensor including three detectors and a manufacturing method of the compound sensor.

### BACKGROUND ART

Document 1 (JP 2011-242371 A) describes a compound sensor manufactured based on a sensor wafer and a cap wafer. The sensor wafer includes an acceleration sensor and an angular velocity sensor. The acceleration sensor is bonded and sealed in an atmospheric pressure environment by bonding of the sensor wafer and the cap wafer in the atmospheric pressure environment. The angular velocity sensor is bonded and sealed in a vacuum environment by deformation of bumps due to application of heat and a load to the sensor wafer and the cap wafer in the vacuum environment.

The compound sensor described in Document 1 is structured such that the acceleration sensor (acceleration detector) and the angular velocity sensor (angular velocity detector) are housed in respective packages.

### SUMMARY

It is an object of the present disclosure to provide a compound sensor and a manufacturing method which enable detection accuracy to be suppressed from decreasing while three detectors are collected in a single package.

A compound sensor according to an aspect of the present disclosure includes a package, a first acceleration detector, a second acceleration detector, and an angular velocity detector. The package has a first cavity, a second cavity, and a third cavity in an interior of the package. The first acceleration detector is disposed in the first cavity. The second acceleration detector is disposed in the second cavity. The angular velocity detector is disposed in the third cavity. An upper limit value of acceleration detectable by the first acceleration detector is smaller than an upper limit value of acceleration detectable by the second acceleration detector. An inner pressure of the first cavity is higher than an inner pressure of the second cavity. An inner pressure of the third cavity is lower than the inner pressure of the second cavity.

A manufacturing method according to an aspect of the present disclosure is a method for manufacturing a compound sensor provided with a package including a bottom wall, a side part, and a cover, and the method includes the following first to fourth steps. The first step is a step of forming a first acceleration detector, a second acceleration detector, and an angular velocity detector respectively in a first space, a second space, and a third space provided in the side part. The second step is a step of attaching the side part between the bottom wall and the cover and forming a first cavity including the first space, a second cavity including the second space, and a third cavity including the third space between the bottom wall and the cover. The third step is a step of forming, in the cover, at least one first through hole and at least one second through hole respectively placing the first cavity and the second cavity in communication with an outside. The fourth step is performed after the second step. The fourth step is a step of filling each of the at least one first through hole and the at least one second through hole with a getter material which is configured to adsorb a gas. An upper limit value of acceleration detectable by the first acceleration detector is smaller than an upper limit value of acceleration detectable by the second acceleration detector. An inner pressure of the first cavity is higher than an inner pressure of the second cavity. An inner pressure of the third cavity is lower than the inner pressure of the second cavity. A total opening area of the at least one second through hole is greater than a total opening area of the at least one first through hole.

A manufacturing method according to another aspect of the present disclosure is a method for manufacturing a compound sensor provided with a package including a bottom wall, a side part, and a cover, and the method includes the following first to third steps and fifth step. The first step is a step of forming a first acceleration detector, a second acceleration detector, and an angular velocity detector respectively in a first space, a second space, and a third space provided in the side part. The second step is a step of attaching the side part between the bottom wall and the cover and forming a first cavity including the first space, a second cavity including the second space, and a third cavity including the third space between the bottom wall and the cover. The third step is a step of forming, in the cover, at least one first through hole and at least one second through hole respectively placing the first cavity and the second cavity in communication with an outside. The fifth step is a step of filling each of the at least one first through hole and the at least one second through hole with an outgassing material which is configured to produce a gas. An upper limit value of acceleration detectable by the first acceleration detector is smaller than an upper limit value of acceleration detectable by the second acceleration detector. An inner pressure of the first cavity is higher than an inner pressure of the second cavity. An inner pressure of the third cavity is lower than the inner pressure of the second cavity. A total opening area of the at least one first through hole is greater than a total opening area of the at least one second through hole.

### BRIEF DESCRIPTION OF THE DRAWINGS

The figures depict one or more implementations in accordance with the present teaching, by way of example only, not by way of limitations. In the figures, like reference numerals refer to the same or similar elements.

FIG. 1 is a sectional side view of a compound sensor according to a first embodiment;

FIG. 2 is a sectional side view of a base and a plurality of detectors of the compound sensor;

FIG. 3 is a sectional side view of a manufacturing step of the compound sensor;

FIG. 4 is a sectional side view of a manufacturing step of the compound sensor;

FIG. 5 is a plan view of a manufacturing step of the compound sensor;

FIG. 6 is a sectional side view of a manufacturing step of the compound sensor;

FIG. 7 is a sectional side view of a manufacturing step of the compound sensor;

FIG. 8 is a flowchart of a manufacturing method of the compound sensor;

FIG. 9 is an enlarged view of a side cross section of the compound sensor;

FIG. 10 is an illustrative view of a manufacturing step of the compound sensor;

FIG. 11 is a plan view of a main part of a compound sensor according to a first variation of the first embodiment;

FIG. 12 is a sectional side view of a compound sensor according to a second embodiment;

FIG. 13 is a sectional side view of a compound sensor according to a third embodiment;

and

FIG. 14 is a sectional side view of a compound sensor according to a first variation of the third embodiment.

### DETAILED DESCRIPTION

In each of the following embodiments, a compound sensor and a manufacturing method of the present disclosure will be described with reference to the drawings. Note that each of the following embodiments is merely a part of various embodiments of the present disclosure. Various modifications may be made to the following embodiments depending on design and the like as long as the object of the present disclosure is achieved. Moreover, the embodiments, inclusively of variations, described below may accordingly be combined with each other. Moreover, figures described in the following embodiments are schematic views, and therefore, the ratio of sizes and the ratio of thicknesses of components in the drawings do not necessarily reflect actual dimensional ratios.

### First Embodiment

### (Overview)

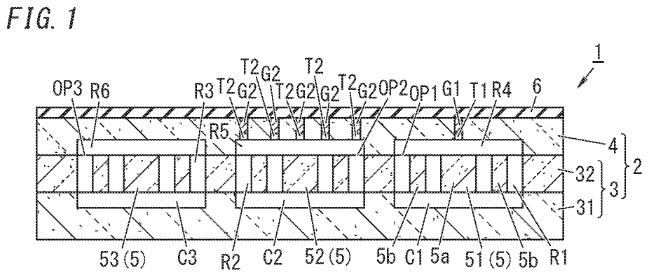

As shown in FIG. 1, a compound sensor 1 of the present embodiment includes a package 2, a first acceleration detector 51, a second acceleration detector 52, and an angular velocity detector 53. Each of the first acceleration detector 51, the second acceleration detector 52, and the angular velocity detector 53 is an example of a detector 5 which is housed in the package 2 to detect a physical quantity. Four or more detectors 5 may be provided. In the present embodiment, three detectors 5 are provided.

The package 2 has a first cavity C1 (hollow), a second cavity C2, and a third cavity C3 in an interior of the package 2. The first acceleration detector 51 is disposed in the first cavity C1. The second acceleration detector 52 is disposed in the second cavity C2. The angular velocity detector 53 is disposed in the third cavity C3. An upper limit value of acceleration detectable by the first acceleration detector 51 is smaller than an upper limit value of acceleration detectable by the second acceleration detector 52. An inner pressure of the first cavity C1 is higher than an inner pressure of the second cavity C2. An inner pressure of the third cavity C3 is lower than the inner pressure of the second cavity C2.

Each of the acceleration detectors (the first acceleration detector 51 and the second acceleration detector 52) has a natural resonance frequency according to the upper limit value of the acceleration thus detectable. A vibration of each acceleration detector at the resonance frequency may be a cause of a decrease in detection accuracy. In order to suppress the vibration of each acceleration detector at the resonance frequency, each acceleration detector has to be disposed in an environment of an inner pressure according to the resonance frequency to cause a dumping effect produced by a gas (effect of suppressing the acceleration detector from vibrating) to have a magnitude according to the resonance frequency. That is, a dumping effect for the first acceleration detector 51 and a dumping effect for the second acceleration detector 52 have to be made different. To achieve this, in the compound sensor 1 of the present embodiment, the inner pressure of the first cavity C1 and the inner pressure of the second cavity C2 are made different as described above. Therefore, the compound sensor 1 of the present embodiment enables the detection accuracy of each acceleration detector to be suppressed from decreasing.

Further, if the angular velocity detector 53 is not disposed in a low-pressure environment in which the dumping effect produced by the gas (effect of suppressing the angular velocity detector 53 from vibrating) can be suppressed, a property related to the detection accuracy of the angular velocity detector 53 may degrade. Therefore, as described above, the inner pressure of the third cavity C3 in which the angular velocity detector 53 is disposed is made lower than the inner pressure of the second cavity C2. Thus, the detection accuracy of the angular velocity detector 53 can be suppressed from decreasing.

Thus, according to the compound sensor 1 of the present embodiment, the detection accuracy of each detector 5 can be suppressed from decreasing while the first acceleration detector 51, the second acceleration detector 52, and the angular velocity detector 53 are collected in a single package 2.

A desirable ratio between the inner pressure of the first cavity C1 and the inner pressure of the second cavity C2 differs depending on, for example, properties of the first acceleration detector 51 and the second acceleration detector 52. In order to suppress the vibration of each acceleration detector at the resonance frequency, as an example, the inner pressure of the first cavity C1 is √5 or more times the inner pressure of the second cavity C2.

The upper limit values of acceleration detectable by the first acceleration detector 51 and the second acceleration detector 52 depend on, for example, structures of the respective acceleration detectors. For example, each acceleration detector includes a movable part 5a (see FIG. 1) which is displaced in accordance with acceleration, and when the acceleration exceeds the upper limit value, the movable part 5a collides with another component, and therefore, each acceleration detector can no longer detect the acceleration.

The compound sensor 1 is used, for example, to detect the occurrence of the collision of an object. In this case, suppressing the detection accuracy of each detector 5 from decreasing enables the occurrence of the collision to be more accurately detected.

In addition, the compound sensor 1 is applicable to various applications. For example, the compound sensor 1 may be a sensor to be disposed on an automobile, and the first acceleration detector 51, the second acceleration detector 52, and the angular velocity detector 53 of the compound sensor 1 are used for respective applications of the automobile. The applications of the automobile are, for example, detection of a travel distance, detection of the orientation of an automobile body, and detection of a collision of an object with the automobile body.

### (Details)

### (1) Overall Structure

As shown in FIG. 1, the compound sensor 1 of the present embodiment includes the package 2, the first acceleration detector 51, the second acceleration detector 52, the angular velocity detector 53, a protection film 6, and a plurality of getter materials G1 and G2. Each of the plurality of getter materials G1 and G2 is a material which adsorbs a gas. Each of the plurality of getter materials G1 and G2 adsorbs the gas, thereby adjusting the inner pressure of the first cavity C1 and the inner pressure of the second cavity C2.

### (2) Package

The package 2 is made of, for example, a material including a silicon semiconductor. The package 2 includes a base 3 and a cover 4. In the following description, the cover 4 is disposed upward of the base 3, and the base 3 is disposed downward of the cover 4. Note that these definitions are not intended to limit directions of use of the compound sensor 1.

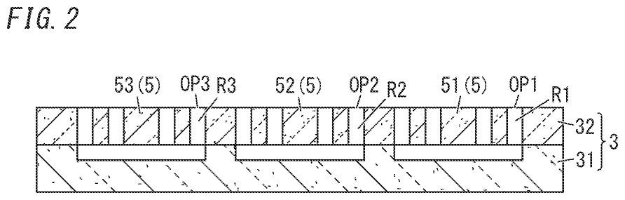

In FIG. 2, only the base 3 and the plurality of detectors 5 of components of the compound sensor 1 are shown. As shown in FIGS. 1 and 2, the base 3 includes a bottom wall 31 and a side part 32.

As shown in FIG. 2, the base 3 has a first recess R1, a second recess R2, and a third recess R3. The first recess R1 is part of the first cavity C1. The second recess R2 is part of the second cavity C2. The third recess R3 is part of the third cavity C3. The bottom wall 31 has a bottom surface of each of the first recess R1, the second recess R2, and the third recess R3. The side part 32 protrudes from the bottom wall 31 to form at least part of a side surface of each of the first recess R1, the second recess R2, and the third recess R3. When viewed from above, each of the first recess R1, the second recess R2, and the third recess R3 is surrounded by the side part 32.

The base 3 further has a first opening OP1, a second opening OP2, and a third opening OP3. The first opening OP1, the second opening OP2, and the third opening OP3 are respectively at upper ends of the first recess R1, the second recess R2, and the third recess R3. Through the first opening OP1, the first recess R1 is opened to the outside of the base 3. Through the second opening OP2, the second recess R2 is opened to the outside of the base 3. Through the third opening OP3, the third recess R3 is opened to the outside of the base 3.

The cover 4 has a plate shape. The cover 4 is fixed to the base 3. The cover 4 covers the first opening OP1, the second opening OP2, and the third opening OP3.

The cover 4 has a fourth recess R4, a fifth recess R5, and a sixth recess R6. The first recess R1 and the fourth recess R4 are connected to each other such that bottom surfaces of the first recess R1 and the fourth recess R4 face each other. The second recess R2 and the fifth recess R5 are connected to each other such that bottom surfaces of the second recess R2 and the fifth recess R5 face each other. The third recess R3 and the sixth recess R6 are connected to each other such that bottom surfaces of the third recess R3 and the sixth recess R6 face each other.

The first cavity C1 is a hollow including the first recess R1 and the fourth recess R4. The second cavity C2 is a hollow including the second recess R2 and the fifth recess R5. The third cavity C3 is a hollow including the third recess R3 and the sixth recess R6.

The cover 4 has one first through hole T1 and two or more second through holes T2.

The first through hole T1 places the first cavity C1 in communication with the outside of the cover 4. Specifically, the first through hole T1 extends from the bottom surface of the fourth recess R4 through an upper surface (a surface on an opposite side of the cover 4 from the fourth recess R4). The first through hole T1 has a longitudinal direction along an up/down direction.

Each of the two or more second through holes T2 places the second cavity C2 in communication with the outside of the cover 4. Specifically, each of the two or more second through holes T2 extends from the bottom surface of the fifth recess R5 through the upper surface of the cover 4 (the surface on an opposite side of the cover 4 from the fifth recess R5). Each of the two or more second through holes T2 has a longitudinal direction along the up/down direction.

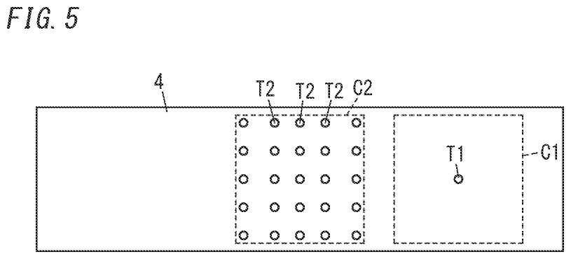

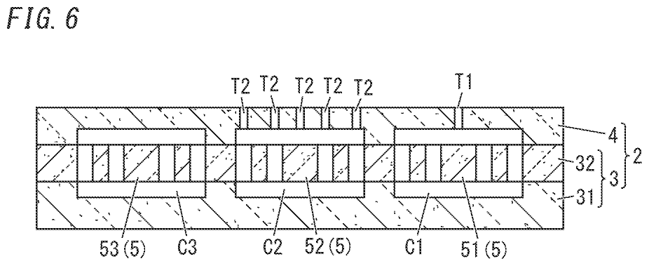

FIGS. 5 and 6 show the package 2 before covered with the protection film 6 in a manufacturing step of the compound sensor 1. As shown in FIG. 5, the first through hole T1 is at a location overlapping the center of the first cavity C1 when viewed from above. That is, the center of the first cavity C1 and the center of a region in which the first through hole T1 is formed overlap each other. Moreover, the center of the second cavity C2 and the center of a region in which the two or more second through holes T2 are formed overlap each other when viewed from above. When viewed from above, the two or more second through holes T2 are formed in the region overlapping the second cavity C2. The two or more second through holes T2 are disposed at equal intervals.

### (3) Protection Film

The package 2 has an upper surface covered with the protection film 6. That is, the upper surface of the cover 4 (surface on an opposite side of the cover 4 from the first cavity C1, the second cavity C2, and the third cavity C3) is covered with the protection film 6. The protection film 6 also covers the first through hole T1 and the two or more second through holes T2 in the cover 4.

The protection film 6 is, for example, a silicon oxide film or a silicon nitride film. Alternatively, the protection film 6 may be made of, for example, a polyimide-containing material such as polyimide polybenzoxazole (PBO).

### (4) Three Detectors

The compound sensor 1 includes the first acceleration detector 51, the second acceleration detector 52, and the angular velocity detector 53 as the three detectors 5. Each of the three detectors 5 includes the movable part 5a and a plurality of (in FIG. 1, two) detection elements 5b. The movable part 5a is displaced in accordance with acceleration or angular velocity. The detection elements 5b are disposed around the movable part 5a. The detection elements 5b input signals to the movable part 5a, or the movable part 5a outputs a signal to the detection elements 5b.

In each of the first acceleration detector 51 and the second acceleration detector 52, when acceleration is applied, the acceleration displaces the movable part 5a. A signal according to the amount of the displacement is output as an acceleration signal representing the acceleration via the detection elements 5b.

In the angular velocity detector 53, when an angular velocity is applied while the movable part 5a is driven and vibrated, a Coriolis force displaces the movable part 5a. A signal according to the amount of the displacement is output as an angular velocity signal representing the angular velocity via the detection elements 5b.

### (5) Getter Materials

The compound sensor 1 includes a getter material G1 and two or more getter materials G2 as a plurality of getter materials. Each of the getter material G1 and the two or more getter materials G2 is a member which absorbs a gas and which is, for example, a zirconium (Zr) alloy or a titanium (Ti) alloy. More specifically, each of the getter material G1 and the two or more getter materials G2 is, for example, a Zr—V—Fe alloy, a Zr—Al—Ni alloy, a Ti—Zr—V alloy, a Ti—Cr—V alloy, or a Ti—Zr—Cr—V alloy. The gas adsorbed by the getter material G1 and the two or more getter materials G2 is, for example, hydrogen, nitrogen, oxygen, carbon dioxide, carbon monoxide, methane, ammonia, water vapor, hydrogen sulfide, or an organic compound.

The number of getter materials G1 is equal to the number of the first through holes T1. The number of the getter materials G2 is equal to the number of second through holes T2.

The first through hole T1 is filled with the getter material G1. Each of the two or more second through holes T2 is filled with the getter material G2.

The first cavity C1 is hermetically sealed with the getter material G1. The second cavity C2 is hermetically sealed with the two or more getter materials G2. Moreover, the first through hole T1 and the two or more second through holes T2 are respectively closed by the getter material G1 and the two or more getter materials G2, and on the getter material G1 and the two or more getter materials G2, the protection film 6 is formed.

The total opening areas of the two or more second through holes T2 is greater than the opening area of the first through hole T1. More specifically, as shown in FIG. 5, the opening area per first through hole T1 is substantially equal to the opening area per second through hole T2, but the number of second through holes T2 is greater than the number of first through holes T1.

### (6) Manufacturing Method

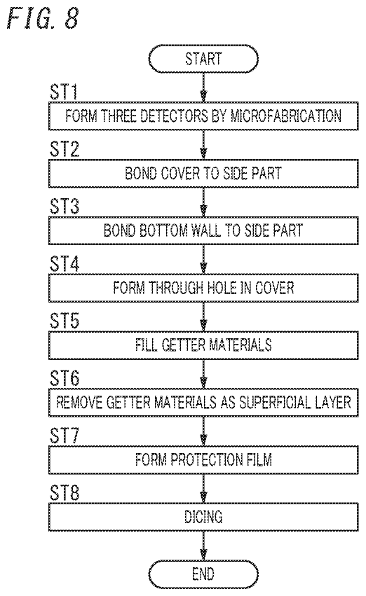

Next, with reference to FIG. 1 and FIGS. 3 to 8, the manufacturing method of the compound sensor 1 will be described. The compound sensor 1 is manufactured by using one or more manufacturing devices. Note that the flowchart shown in FIG. 8 merely shows an example of the manufacturing method of the compound sensor 1, and the order of steps included in the manufacturing method may be changed, or a step(s) may accordingly be added or omitted.

First of all, the bottom wall 31, the side part 32 supporting the three detectors 5, and a cover 4P serving as a base of the cover 4 are individually formed.

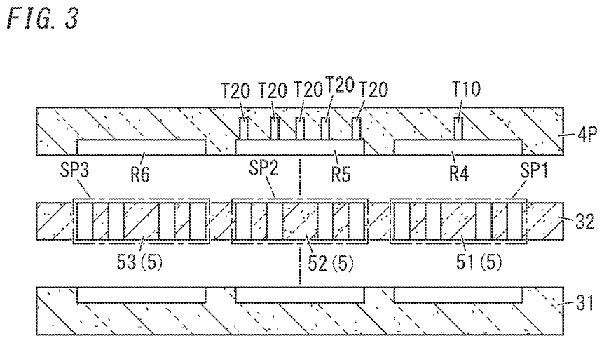

More specifically, a material (silicon wafer) serving as a base of the side part 32 is processed into the side part 32 and the three detectors 5 (step ST1 in FIG. 8). As shown in FIG. 3, the side part 32 includes a first space SP1 in which the first acceleration detector 51 is disposed, a second space SP2 in which the second acceleration detector 52 is disposed, and a third space SP3 in which the angular velocity detector 53 is disposed. The first space SP1, the second space SP2, and the third space SP3 penetrate the side part 32 in the up/down direction.

A system including the side part 32 and the three detectors 5 is formed by a microfabrication technique and is a so-called microelectromechanical system (MEMS).

Moreover, similarly to the cover 4, the cover 4P has the fourth recess R4, the fifth recess R5, and the sixth recess R6. Further, the cover 4P has a recess T10 serving as a base of the first through hole T1 and two or more recesses T20 serving as bases of the two or more second through holes T2. The recess T10 is formed in the bottom surface of the fourth recess R4. The recesses T20 are formed in the bottom surface of the fifth recess R5.

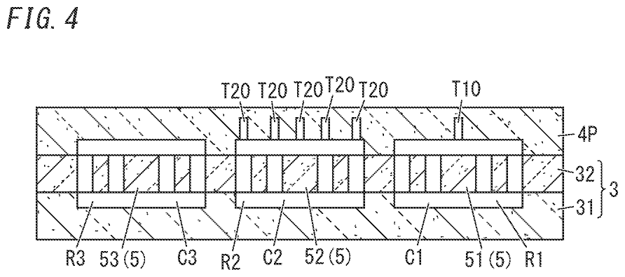

Then, in a lower-pressure (e.g., vacuum) environment than the atmospheric pressure, the cover 4P is bonded to an upper surface of the side part 32 (step ST2), and the bottom wall 31 is bonded to a lower surface of the side part 32 (step ST3) as shown in FIG. 4. Whichever of the cover 4P and the bottom wall 31 may first be bonded to the side part 32.

The bottom wall 31 is bonded to the side part 32, thereby forming the first recess R1, the second recess R2, and the third recess R3. Here, the first acceleration detector 51, the second acceleration detector 52, and the angular velocity detector 53 are respectively disposed in the first recess R1, the second recess R2, and the third recess R3. The first recess R1, the second recess R2, and the third recess R3 respectively include the first space SP1, the second space SP2, and the third space SP3.

Moreover, the bottom wall 31 and the cover 4P are bonded to the side part 32, thereby forming the first cavity C1, the second cavity C2, and the third cavity C3 between the bottom wall 31 and the cover 4P.

Then, the first through hole T1 and the two or more second through holes T2 are formed in the cover 4P, thereby forming the cover 4 as shown in FIG. 6 (step ST4). More specifically, an upper portion of the cover 4P is scraped off such that the recess T10 and the two or more recesses T20 are connected to a space above the cover 4P. The recess T10 and the two or more recesses T20 connected to the space above the cover 4P respectively correspond to the first through hole T1 and the two or more second through holes T2. That is, the first through hole T1 and the two or more second through holes T2 are formed by scraping off the upper portion of the cover 4P.

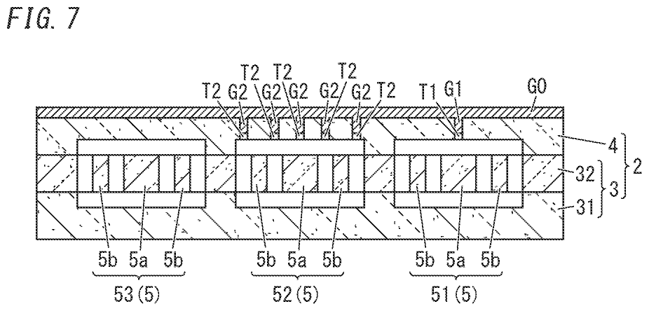

Next, the first through hole T1 and the two or more second through holes T2 are respectively filled with the getter materials G1 and G2 (step ST5). Here, the getter materials G1 and G2 are made of the same material. Sputtering the material (e.g., a titanium alloy) for the getter materials G1 and G2 is sputtered onto the upper surface of the cover 4 fills the first through hole T1 and the two or more second through holes T2 with the getter materials G1 and G2 and forms a layer of a getter material G0 on the upper surface of the cover 4 as shown in FIG. 7. The getter material G0 is removed (step ST6), and thereafter, the protection film 6 is formed as shown in FIG. 1 (step ST7). As the sputtering, for example, magnetron sputtering is suitable.

In the manufacturing steps of the compound sensor 1, a wafer including a plurality of compound sensors 1 are formed by the steps described above. The wafer is then diced into a plurality of compound sensors 1 (step ST8). Thus, the plurality of compound sensors 1 are finished.

In steps ST2, and ST3, the cover 4P and the bottom wall 31 are bonded to the side part 32 in the lower-pressure environment than the atmospheric pressure, and therefore, the inner pressure of the third cavity C3 hermetically sealed with the cover 4P (or the cover 4) is equal to the air pressure of the environment.

In a state where the first through hole T1 and the two or more second through holes T2 have been formed in the cover 4, the package 2 is placed under an atmospheric pressure condition. In this case, air outside the first cavity C1 and the second cavity C2 is taken in the first cavity C1 and the second cavity C2 respectively through the first through hole T1 and the two or more second through holes T2, and the inner pressure of each of the first cavity C1 and the second cavity C2 equals the atmospheric pressure. However, the getter materials G1 and G2 are filled in step ST5, and the getter materials G1 and G2 adsorb a gas, thereby reducing the inner pressures of the first cavity C1 and the second cavity C2. The first cavity C1 is subjected to the getter material G1 filled in the first through hole T1, and the second cavity C2 is subjected to the two or more getter materials G2 filled in the two or more second through holes T2. The total opening area of the two or more second through holes T2 is greater than the opening area of the first through hole T1. Therefore, the amount of the gas adsorbed by the two or more getter materials G2 in the second cavity C2 is greater than the amount of the gas adsorbed by the getter material G1 in the first cavity C1. As a result, the inner pressure of the first cavity C1 is higher than the inner pressure of the second cavity C2.

When the above contents are summarized, the manufacturing method of the compound sensor 1 of the present embodiment includes the following first to fourth steps. The first step (step ST1) is a step of forming the first acceleration detector 51, the second acceleration detector 52, and the angular velocity detector 53 respectively in the first space SP1, the second space SP2, and the third space SP3 provided in the side part 32. The second step (step ST2, ST3) is a step of attaching the side part 32 between the bottom wall 31 and the cover 4 and forming the first cavity C1 including the first space SP1, the second cavity C2 including the second space SP2, and the third cavity C3 including the third space SP3 between the bottom wall 31 and the cover 4. The third step (step ST4) is a step of forming, in the cover 4, at least one first through hole T1 and at least one second through hole T2 respectively placing the first cavity C1 and the second cavity C2 in communication with the outside. The fourth step (step ST5) is performed after the second step. The fourth step is a step of filling each of the at least one first through hole T1 and the at least one second through hole T2 respectively with the getter materials G1 and G2 which are configured to adsorb a gas. The upper limit value of acceleration detectable by the first acceleration detector 51 is smaller than the upper limit value of acceleration detectable by the second acceleration detector 52. The inner pressure of the first cavity C1 is higher than the inner pressure of the second cavity C2. The inner pressure of the third cavity C3 is lower than the inner pressure of the second cavity C2. The total opening area of the at least one second through hole T2 is greater than the total opening area of the at least one first through hole T1.

The order of the steps may accordingly be changed. For example, after the at least one first through hole T1 and the at least one second through hole T2 are formed in the cover 4, the cover 4 may be attached to the side part 32.

### (7) Dimensions of First and Second Through Holes

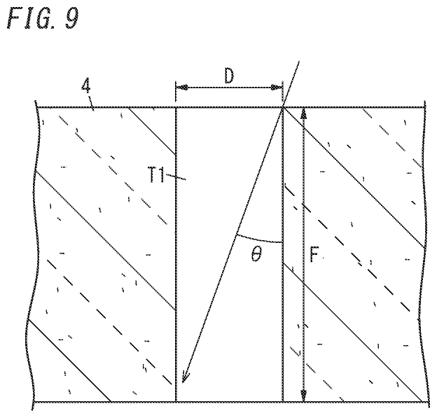

FIG. 9 is an enlarged view of the first through hole T1. A maximum width of the first through hole T1 is defined as D, and the depth of the first through hole T1 is defined as F. The first through hole T1 is, for example, a round hole, and the maximum width D is the diameter.

The getter material G1 may be filled in the first through hole T1 by sputtering. That is, a material for the getter material G1 enters the first through hole T1 in the form of a particle. As F/D decreases, the possibility that sputtering particles enter the first cavity C1 through the first through hole T1 increases. In order to suppress the sputtering particles from adhering to the first acceleration detector 51 disposed in the first cavity C1, the F/D is preferably a relatively large value.

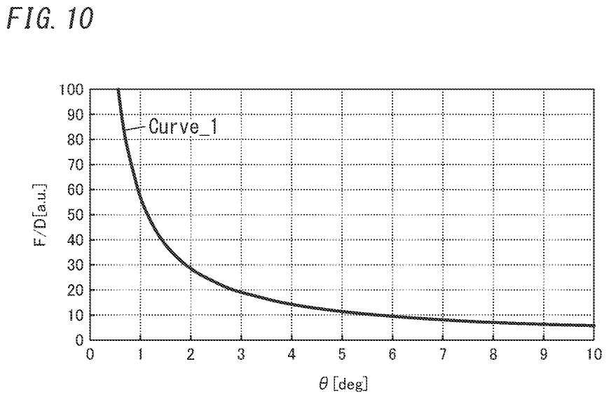

In FIG. 10, Curve_1 shows a minimum F/D with which the sputtering particles can enter the first cavity C1 through the first through hole T1 when the incidence angle of the sputtering particle in the magnetron sputtering is θ. For example, when θ=5.7°, a F/D of less than 10 allows the sputtering particles to enter the first cavity C1 through the first through hole T1. Thus, in this case, the F/D is preferably greater than or equal to 10.

A main distribution of the incidence angle θ of the sputtering particles is easily set to about 10°. From FIG. 10, when θ=10°, the F/D is preferably greater than or equal to 6. The condition that 10≤F/D is preferably satisfied in order to provide a sufficient margin.

Here, it has been explained that the F/D of the first through hole T1 is preferably greater than or equal to 10, and the same applies to each of the two or more second through holes T2. That is, the F/D of each of the two or more second through holes T2 is preferably greater than or equal to 10.

Moreover, when the F/D is greater than 100, producing the first through hole T1 and the second through holes T2 becomes difficult. Therefore, the F/D of each of the first through hole T1 and the two or more second through holes T2 is preferably less than or equal to 100.

### Variations of First Embodiment

Variations of the first embodiment will be enumerated below. The variations described below may accordingly be combined with each other. In the following description, the configuration of the first embodiment described above is referred to as a basic example 1. Components similar to those in the basic example 1 are denoted by the same reference signs, and the description thereof will be omitted.

### First Variation of First Embodiment

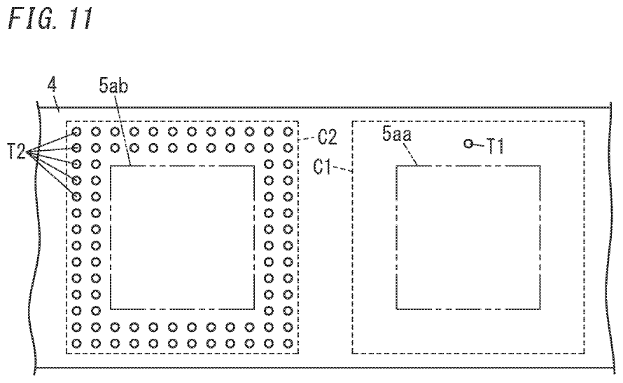

FIG. 11 is a view of a part of the cover 4 viewed in a direction in which the base 3 and the cover 4 face each other. Note that illustration of the protection film 6 and the two or more getter materials G2 are omitted.

As shown in FIG. 11, the two or more second through holes T2 are disposed around a region 5ab overlapping the movable part 5a of the second acceleration detector 52 when viewed in the direction in which the base 3 and the cover 4 face each other. More specifically, the two or more second through holes T2 are disposed outside the region 5ab and in a region overlapping the second cavity C2. The two or more second through holes T2 are disposed to surround the region 5ab.

The two or more second through holes T2 are disposed around the region 5ab, thereby reducing the possibility that the getter materials G2 adhere to the movable part 5a.

Moreover, similarly, the first through hole T1 is preferably disposed around a region 5aa overlapping the movable part 5a of the first acceleration detector 51 when viewed in the direction in which the base 3 and the cover 4 face each other. This enables the possibility that the getter material G1 adheres to the movable part 5a to be reduced.

### Other Variations of First Embodiment

The first recess R1 or the first space SP1 may be the entirety of the first cavity C1 but not part of the first cavity C1. The second recess R2 or the second space SP2 may be the entirety of the second cavity C2 but not part of the second cavity C2. The third recess R3 or the third space SP3 may be the entirety of the third cavity C3 but not part of the third cavity C3.

Each of the number of first through holes T1 and the number of second through holes T2 may be one or may be two or more. Further, the total opening area of the at least one second through hole T2 is preferably greater than the total opening area of the at least one first through hole T1.

In the basic example 1, the second cavity C2 is arranged between the first cavity C1 and the third cavity C3, but such an arrangement is not essential.

The first through hole T1 does not have to be filled with the getter material G1. In this case, the inner pressure of the first cavity C1 is equal to the atmospheric pressure.

### Second Embodiment

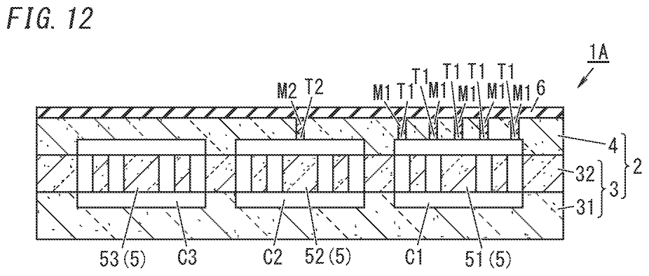

Hereinafter, a compound sensor 1A and a manufacturing method according to a second embodiment will be described with reference to FIG. 12. Components similar to those in the basic example 1 are denoted by the same reference signs, and the description thereof will be omitted.

The compound sensor 1A of the present embodiment is different from the basic example 1 in terms of the number of first through holes T1 and the number of second through holes T2. Moreover, the compound sensor 1A of the present embodiment is different from the basic example 1 in that a plurality of outgassing materials M1 and M2 are used alternatively to the plurality of getter materials G1 and G2.

A cover 4 has two or more first through holes T1 placing a first cavity C1 in communication with the outside. The cover 4 further has one second through hole T2 placing a second cavity C2 in communication with the outside.

The compound sensor 1A includes two or more outgassing materials M1 and one outgassing material M2. The outgassing materials M1 and M2 are members which produce a gas, and the gas is, for example, argon (Ar) gas. The outgassing materials M1 and M2 are formed by, for example, sputtering metal including titanium or chrome in an environment in which the argon gas has been injected. Moreover, after the outgassing materials M1 and M2 are formed in the form of a coating by sputtering, argon may be injected into the outgassing materials M1 and M2 by, for example, argon plasma irradiation.

In order to set the amount of the argon gas to be produced to an adequate level, the atomic percentage “n” of argon atoms in each of the plurality of outgassing materials M1 and M2 preferably satisfies the condition that 0.1≤n. Moreover, the atomic percentage “n” of argon atoms in each of the plurality of outgassing materials M1 and M2 also preferably satisfies the condition that n≤20. For example, when the outgassing material M1 consists of a titanium atom and an argon atom, and the ratio of the number of titanium atoms to the number of argon atoms is 9:1, the atomic percentage n of argon atoms in the outgassing material M1 is n=1/(9+1)×100=10.

The number of outgassing materials M1 is equal to the number of first through holes T1. The number of outgassing materials M2 is equal to the number of second through holes T2.

Each of the two or more first through holes T1 is filled with the outgassing material M1. The second through hole T2 is filled with the outgassing material M2.

The first cavity C1 is sealed with the two or more outgassing materials M1. The second cavity C2 is sealed with the outgassing material M2. Moreover, the two or more first through holes T1 and the second through hole T2 are respectively closed with the two or more outgassing materials M1 and the outgassing material M2, and on the two or more outgassing materials M1 and the outgassing material M2, a protection film 6 is formed.

The total opening area of the two or more first through holes T1 is greater than the opening area of the second through hole T2. More specifically, the opening area per first through holes T1 and the opening area per second through hole T2 are substantially equal to each other, but the number of first through holes T1 is greater than the number of second through holes T2.

The plurality of outgassing materials M1 and M2 produce a gas, thereby adjusting the inner pressure of the first cavity C1 and the inner pressure of the second cavity C2. The inner pressure of the first cavity C1 is higher than the inner pressure of the second cavity C2. An inner pressure of a third cavity C3 is lower than the inner pressure of the second cavity C2.

More specifically, the plurality of outgassing materials M1 and M2 produce the gas, thereby increasing the inner pressures of the first cavity C1 and the second cavity C2. The first cavity C1 is subjected to the two or more outgassing materials M1 filled in the two or more first through holes T1, and the second cavity C2 is subjected to the outgassing material M2 filled in the second through hole T2. The total opening area of the two or more first through holes T1 is greater than the opening area of the second through hole T2. Therefore, the amount of the gas produced in the first cavity C1 from the two or more outgassing materials M1 is greater than the amount of the gas produced in the second cavity C2 from the outgassing material M2. As a result, the inner pressure of the first cavity C1 is higher than the inner pressure of the second cavity C2.

More specifically, after the cover 4 and a bottom wall 31 are bonded to a side part 32, a package 2 is placed under the atmospheric pressure condition. In this case, air outside the first cavity C1 and the second cavity C2 is taken in the first cavity C1 and the second cavity C2 respectively through the two or more first through holes T1 and the second through hole T2, and the inner pressure of each of the first cavity C1 and the second cavity C2 equals the atmospheric pressure. Thereafter, the outgassing materials M1 and M2 are filled, and the outgassing materials M1 and M2 produce the gas, thereby increasing the inner pressures of the first cavity C1 and the second cavity C2.

A positional relationship among the two or more first through holes T1, the first cavity C1, and a first acceleration detector 51 of the present embodiment is similar to, for example, the positional relationship among the two or more second through holes T2, the second cavity C2, and a second acceleration detector 52 of the basic example 1. That is, as an example, the center of the first cavity C1 and the center of a region where the two or more first through holes T1 are provided overlap each other when viewed from above. When viewed from above, the two or more first through holes T1 are provided in a region overlapping the first cavity C1. The two or more first through holes T1 are arranged at equal intervals from each other.

Moreover, at a location overlapping the center of the second cavity C2 when viewed from above, the second through hole T2 is formed.

Moreover, similarly to the first variation of the first embodiment, the two or more first through holes T1 are preferably provided around a region overlapping a movable part 5a of the first acceleration detector 51 when viewed in a direction in which a base 3 and the cover 4 face each other. Moreover, the second through hole T2 is also preferably disposed around a region overlapping a movable part 5a of the second acceleration detector 52 when viewed in the direction in which the base 3 and the cover 4 face each other.

Similarly to the basic example 1, the ratio F/D of the depth to a maximum width of each of the two or more first through holes T1 and the second through hole T2 is preferably greater than or equal to 10. Moreover, the F/D is preferably less than or equal to 100.

Next, only differences of a manufacturing method of the compound sensor 1A of the present embodiment from the basic example 1 will be described. In step ST4 (see FIG. 8) of forming a through hole in a cover 4P, the two or more first through holes T1 connected to the first cavity C1 and the second through hole T2 connected to the second cavity C2 are formed. Then, alternatively to step ST5 (see FIG. 8) of filling the getter materials G1 and G2 in the through holes (the first through hole T1 and the two or more second through holes T2) by sputtering in the basic example 1, a step of filling the outgassing materials M1 and M2 in the through holes (the two or more first through holes T1 and the second through hole T2) by sputtering is performed. Thereafter, alternatively to step ST6 (see FIG. 8) of removing the getter material G0 as a superficial layer formed by sputtering, a step of removing an outgassing material as a superficial layer formed by the sputtering is performed.

Thus, the manufacturing method of the compound sensor 1A of the present embodiment includes the following first to third and fifth steps. The first step is a step of forming the first acceleration detector 51, the second acceleration detector 52, and the angular velocity detector 53 respectively in a first space SP1, a second space SP2, and a third space SP3 provided in the side part 32. The second step is a step of attaching the side part 32 between the bottom wall 31 and the cover 4 and forming the first cavity C1 including the first space SP1, the second cavity C2 including the second space SP2, and the third cavity C3 including the third space SP3 between the bottom wall 31 and the cover 4. The third step is a step of forming, in the cover 4, at least one first through hole T1 and at least one second through hole T2 respectively placing the first cavity C1 and the second cavity C2 in communication with the outside. The fifth step is a step of filling each of the at least one first through hole T1 and each of the at least one second through hole T2 with the outgassing materials M1 and M2 which are configured to produce the gas. An upper limit value of acceleration detectable by the first acceleration detector 51 is smaller than an upper limit value of acceleration detectable by the second acceleration detector 52. An inner pressure of the first cavity C1 is higher than an inner pressure of the second cavity C2. An inner pressure of the third cavity C3 is lower than the inner pressure of the second cavity C2. The total opening area of the at least one first through hole T1 is greater than the total opening area of the at least one second through hole T2.

The order of the steps may accordingly be changed. For example, after the at least one first through hole T1 and the at least one second through hole T2 are formed in the cover 4, the cover 4 may be attached to the side part 32. Moreover, for example, after each of the at least one first through hole T1 and each of the at least one second through hole T2 are filled with the outgassing materials M1 and M2, the cover 4 may be attached to the side part 32.

### Variation of Second Embodiment

Variations of the second embodiment will be enumerated below. The variations described below may accordingly be combined with each other. In the following description, the configuration of the second embodiment described above is referred to as a basic example 2. Components similar to those in the basic example 2 are denoted by the same reference signs, and the description thereof will be omitted.

A first recess R1 or the first space SP1 may be the entirety of the first cavity C1 but not part of the first cavity C1. A second recess R2 or the second space SP2 may be the entirety of the second cavity C2 but not part of the second cavity C2. A third recess R3 or the third space SP3 may be the entirety of the third cavity C3 but not part of the third cavity C3.

Each of the number of first through holes T1 and the number of second through holes T2 may be one or may be two or more. Further, the total opening area of the at least one first through hole T1 is preferably greater than the total opening area of the at least one second through hole T2.

In the basic example 2, the second cavity C2 is arranged between the first cavity C1 and the third cavity C3, but such an arrangement is not essential.

The second through hole T2 does not have to be filled with the outgassing material M2. In this case, the inner pressure of the second cavity C2 is equal to the atmospheric pressure.

The second through hole T2 may be filled with a getter material instead of the outgassing material M2.

The outgassing materials M1 and M2 may be formed by unbalance magnetron (UBM) sputtering. This enables the number of argon atoms included in the outgassing materials M1 and M2 to be increased.

The outgassing materials M1 and M2 are not limited to members which produce the argon gas, but the outgassing materials M1 and M2 are preferably members which produce an inert gas such as a noble gas. The noble gas is, for example, argon, krypton (Kr), or xenon (Xe).

### Third Embodiment

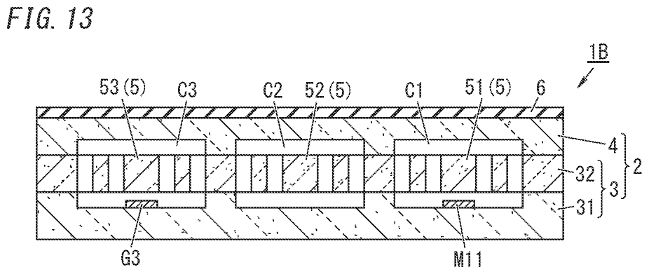

A compound sensor 1B and a manufacturing method according to a third embodiment will be described below with reference to FIG. 13. Components similar to those in the basic example 1 are denoted by the same reference signs, and the description thereof will be omitted.

In the compound sensor 1B of the present embodiment, a cover 4 has neither the first through hole T1 nor the second through hole T2. Thus, the compound sensor 1B includes no getter materials G1 and G2 respectively filled in the first through hole T1 and the second through hole T2.

The compound sensor 1B includes an outgassing material M11 disposed in a first cavity C1 and a getter material G3 disposed in a third cavity C3. The outgassing material M11 produces a gas. The getter material G3 adsorbs a gas.

In a manufacturing step of the compound sensor 1B, the outgassing material M11 is disposed in the first cavity C1, and the getter material G3 is disposed in the third cavity C3. Then, in a predetermined air pressure environment, the cover 4 and a bottom wall 31 are bonded to a side part 32 to hermetically close the first cavity C1, a second cavity C2, and the third cavity C3.

The inner pressure of the second cavity C2 is the predetermined air pressure. In the first cavity C1, the gas is produced from the outgassing material M11, and therefore, the inner pressure is higher than the predetermined air pressure. In the third cavity C3, the getter material G3 adsorbs the gas, and therefore, the inner pressure is lower than the predetermined air pressure.

The composition of the getter material G3 may be similar to the composition of the getter materials G1 and G2 of the basic example 1. The composition of the outgassing material M11 may be similar to the composition of the outgassing materials M1 and M2 of the basic example 2.

### Variations of Third Embodiment

Variations of the third embodiment will be enumerated below. The variations described below may accordingly be combined with each other. In the following description, the configuration of the third embodiment described above is referred to as a basic example 3. Components similar to those in the basic example 3 are denoted by the same reference signs, and the description thereof will be omitted.

### First Variation of Third Embodiment

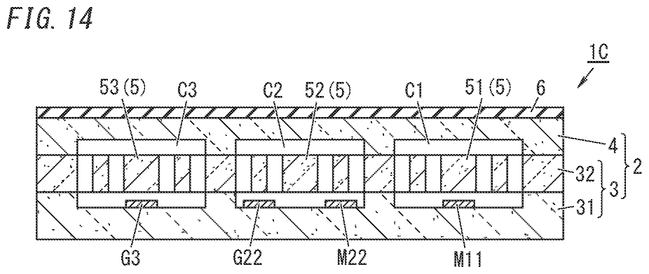

FIG. 14 is a sectional view of a compound sensor 1C of a first variation. As shown in FIG. 14, in the first variation, an outgassing material and a getter material are disposed also in the second cavity C2. That is, the compound sensor 1C further includes an outgassing material M22 and a getter material G22 disposed in the second cavity C2. The other components are similar to those in the basic example 3.

In the first variation, the outgassing material M22 and the getter material G22 enable the inner pressure of the second cavity C2 to be adjusted.

In a manufacturing step of the compound sensor 1C, the cover 4 and the bottom wall 31 are bonded to the side part 32 to hermetically close the second cavity C2 in a predetermined air pressure environment. Thereafter, the outgassing material M22 and the getter material G22 adjust the inner pressure of the second cavity C2. Even when the predetermined air pressure is, for example, the atmospheric pressure, the magnitude of the inner pressure of the second cavity C2 can be made different from the atmospheric pressure. That is, the configuration of the compound sensor 1C of the first variation is suitable for the work of bonding the cover 4 to the base 3 under the atmospheric pressure.

### Other Variations of Third Embodiment

A first recess R1 or a first space SP1 may be the entirety of the first cavity C1 but not part of the first cavity C1. A second recess R2 or a second space SP2 may be the entirety of the second cavity C2 but not part of the second cavity C2. A third recess R3 or a third space SP3 may be the entirety of the third cavity C3 but not part of the third cavity C3.

In the basic example 3, the second cavity C2 is arranged between the first cavity C1 and the third cavity C3, but such an arrangement is not essential.

The outgassing materials M11 and M22 may be formed by unbalance magnetron (UBM) sputtering. This enables the number of argon atoms included in the outgassing materials M11 and M22 to be increased.

The outgassing materials M11 and M22 are not limited to members which produce the argon gas, but the outgassing materials M11 and M22 are preferably members which produce an inert gas such as a noble gas. The noble gas is, for example, argon, krypton (Kr), or xenon (Xe). In particular, the gas produced from the outgassing material M22 is preferably a noble gas which is hardly adsorbed by the getter material G22.

Similarly to the basic example 1 or 2, the cover 4 may have at least one of the first through hole T1 or the second through hole T2 filled with the getter material or the outgassing material.

### SUMMARY

From the embodiments and the like described above, the following aspects are disclosed.

A compound sensor (1; 1A; 1B; 1C) of a first aspect includes a package (2), a first acceleration detector (51), a second acceleration detector (52), and an angular velocity detector (53). The package (2) has a first cavity (C1), a second cavity (C2), and a third cavity (C3) in an interior of the package (2). The first acceleration detector (51) is disposed in the first cavity (C1). The second acceleration detector (52) is disposed in the second cavity (C2). The angular velocity detector (53) is disposed in the third cavity (C3). An upper limit value of acceleration detectable by the first acceleration detector (51) is smaller than an upper limit value of acceleration detectable by the second acceleration detector (52). An inner pressure of the first cavity (C1) is higher than an inner pressure of the second cavity (C2). An inner pressure of the third cavity (C3) is lower than the inner pressure of the second cavity (C2).

This configuration enables the angular velocity detector (53), the first acceleration detector (51) and the second acceleration detector (52), which are different from each other in terms of the upper limit value of the acceleration thus detectable, to be collected in a single package (2). Thus, making the inner pressures different enables detection accuracy to be suppressed from decreasing due to a vibration of each of the first acceleration detector (51) and the second acceleration detector (52) at a resonance frequency. Moreover, reducing the inner pressure of the third cavity (C3) in which the angular velocity detector (53) is disposed enables a property related to the detection accuracy of the angular velocity detector (53) to be suppressed from degrading. Therefore, while the three detectors are collected in a single package (2), the detection accuracy is suppressed from decreasing.

In a compound sensor (1) of a second aspect referring to the first aspect, the package (2) includes a base (3) and a cover (4). The base (3) has a first recess (R1) which is at least part of the first cavity (C1), a second recess (R2) which is at least part of the second cavity (C2), a third recess (R3) which is at least part of the third cavity (C3), a first opening (OP1), a second opening (OP2), and a third opening (OP3) through which the first recess (R1), the second recess (R2), and the third recess (R3) are respectively opened to an outside of the base (3). The cover (4) covers the first opening (OP1), the second opening (OP2), and the third opening (OP3). The cover (4) has at least one first through hole (T1) and at least one second through hole (T2) respectively placing the first cavity (C1) and the second cavity (C2) in communication with the outside. The compound sensor (1) further includes a getter material (G1; G2) which are configured to adsorb a gas. The getter material (G1; G2) is filled in each of the at least one first through hole (T1) and the at least one second through hole (T2). A total opening area of the at least one second through hole (T2) is greater than a total opening area of the at least one first through hole (T1).

With this configuration, the getter material (G1; G2) adsorbs the gas, thereby making the inner pressures different. In addition, the total opening area of the at least one first through hole (T1) and the total opening area of the at least one second through hole (T2) are adjusted, thereby adjusting the inner pressures.

In a compound sensor (1A) according to a third aspect referring to the first aspect, the package (2) includes a base (3) and a cover (4). The base (3) has a first recess (R1) which is at least part of the first cavity (C1), a second recess (R2) which is at least part of the second cavity (C2), a third recess (R3) which is at least part of the third cavity (C3), a first opening (OP1), a second opening (OP2), and a third opening (OP3) through which the first recess (R1), the second recess (R2), and the third recess (R3) are respectively opened to an outside of the base (3). The cover (4) covers the first opening (OP1), the second opening (OP2), and the third opening (OP3). The cover (4) has at least one first through hole (T1) and at least one second through hole (T2) respectively placing the first cavity (C1) and the second cavity (C2) in communication with the outside. The compound sensor (1A) further includes an outgassing material (M1; M2) which is configured to produce a gas. The outgassing material (M1; M2) is filled in each of the at least one first through hole (T1) and each of the at least one second through hole (T2). A total opening area of the at least one first through hole (T1) is greater than a total opening area of the at least one second through hole (T2).

With this configuration, the outgassing material (M1; M2) produces the gas, thereby making the inner pressures different. In addition, the total opening area of the at least one first through hole (T1) and the total opening area of the at least one second through hole (T2) are adjusted, thereby adjusting the inner pressures.

In a compound sensor (1) of a fourth aspect referring to the second aspect, a number of the at least one second through hole (T2) is greater than a number of the at least one first through hole (T1).

With this configuration, the number of the at least one first through hole (T1) and the number of the at least one second through hole (T2) are adjusted, thereby adjusting the inner pressures.

In a compound sensor (1A) of a fifth aspect referring to the third aspect, a number of the at least one first through hole (T1) is greater than a number of the at least one second through hole (T2).

With this configuration, the number of the at least one first through hole (T1) and the number of the at least one second through hole (T2) are adjusted, thereby adjusting the inner pressures.

In a compound sensor (1; 1A) of a sixth aspect referring to any one of the second to fifth aspects, each of the at least one first through hole (T1) and the at least one second through hole (T2) satisfies a condition that 10≤F/D, where D is a maximum width and F is a depth of each of the at least one first through hole (T1) and the at least one second through hole (T2), and D and F are defined for each of the at least one first through hole (T1) and the at least one second through hole (T2).

This configuration reduces the possibility that the getter material (G1; G2) or the outgassing material (M1; M2) reaches the first cavity (C1) or the second cavity (C2) at the time of filling the getter material (G1; G2) or the outgassing material (M1; M2) in the at least one first through hole (T1) and the at least one second through hole (T2).

In a compound sensor (1; 1A) of a seventh aspect referring to any one of the second to sixth aspects, the first acceleration detector (51) includes a movable part (5a) configured to be displaced in accordance with acceleration. When viewed in a direction in which the base (3) and the cover (4) face each other, the at least one first through hole (T1) is provided around a region (5aa) overlapping the movable part (5a) of the first acceleration detector (51).

This configuration reduces the possibility that the getter material (G1; G2) or the outgassing material (M1; M2) adheres to the movable part (5a).

In a compound sensor (1; 1A) of an eighth aspect referring to any one of the second to seventh aspect, the second acceleration detector (52) includes a movable part (5a) configured to be displaced in accordance with acceleration. When viewed in a direction in which the base (3) and the cover (4) face each other, the at least one second through hole (T2) is provided around a region (5ab) overlapping the movable part (5a) of the second acceleration detector (52).

This configuration reduces the possibility that the getter material (G1; G2) or the outgassing material (M1; M2) adheres to the movable part (5a).

A compound sensor (1B; 1C) of a ninth aspect referring to any one of the first to eighth aspects further includes an outgassing material (M11) which is disposed in the first cavity (C1) and which is configured to produce a gas, and a getter material (G3) which is disposed in the third cavity (C3) and which is configured to adsorb a gas.

With this configuration, the getter material (G3) adsorbs the gas, and the outgassing material (M11) produces the gas, thereby making the inner pressures different. In addition, the amount of each of the getter material (G3) and the outgassing material (M11) is adjusted, thereby adjusting the inner pressures.

In a compound sensor (1C) of a tenth aspect referring to the ninth aspect, the outgassing material (M22) and the getter material (G22) are disposed also in the second cavity (C2).

This configuration enables the inner pressure of the second cavity (C2) to be adjusted.

In a compound sensor (1A; 1B; 1C) of an eleventh aspect referring to the third, fifth, ninth, or tenth aspect, an atomic percentage “n” of argon atoms in the outgassing material (M1; M2; M11; M22) satisfies a condition that 0.1≤n.

This configuration enables a sufficient amount of an argon gas produced from the outgassing material (M1; M2; M11; M22) to be secured.

In a compound sensor (1A; 1B; 1C) of a twelfth aspect referring to the third, fifth, ninth, tenth, or eleventh aspect, an atomic percentage “n” of argon atoms in the outgassing material (M1; M2; M11; M22) satisfies a condition that n≤20.

This configuration enables the amount of the argon gas produced from the outgassing material (M1; M2; M11; M22) to be set to an adequate level.

Configurations except for the configuration of the first aspect are not essential configurations for the compound sensor (1; 1A; 1B; 1C) and may thus accordingly be omitted.

A manufacturing method of a thirteenth aspect is a method of manufacturing a compound sensor (1) provided with a package (2) including a bottom wall (31), a side part (32), and a cover (4), and the method includes first to third steps. The first step is a step of forming a first acceleration detector (51), a second acceleration detector (52), and an angular velocity detector (53) respectively in a first space (SP1), a second space (SP2), and a third space (SP3) provided in the side part (32). The second step is a step of attaching the side part (32) between the bottom wall (31) and the cover (4) and forming a first cavity (C1) including the first space (SP1), a second cavity (C2) including the second space (SP2), and a third cavity (C3) including the third space (SP3) between the bottom wall (31) and the cover (4). The third step is a step of forming, in the cover (4), at least one first through hole (T1) and at least one second through hole (T2) respectively placing the first cavity (C1) and the second cavity (C2) in communication with an outside. The fourth step is performed after the second step. The fourth step is a step of filling each of the at least one first through hole (T1) and the at least one second through hole (T2) with a getter material (G1; G2) which is configured to adsorb a gas. An upper limit value of acceleration detectable by the first acceleration detector (51) is smaller than an upper limit value of acceleration detectable by the second acceleration detector (52). An inner pressure of the first cavity (C1) is higher than an inner pressure of the second cavity (C2). An inner pressure of the third cavity (C3) is lower than the inner pressure of the second cavity (C2). A total opening area of the at least one second through hole (T2) is greater than a total opening area of the at least one first through hole (T1).

With this configuration, the getter material (G1; G2) adsorbs the gas, thereby making the inner pressures different. In addition, the total opening area of the at least one first through hole (T1) and the total opening area of the at least one second through hole (T2) are adjusted, thereby adjusting the inner pressures.

A manufacturing method of a fourteenth aspect is a method of manufacturing a compound sensor (1A) provided with a package (2) including a bottom wall (31), a side part (32), and a cover (4), and the method includes first to third and fifth steps. The first step is a step of forming a first acceleration detector (51), a second acceleration detector (52), and an angular velocity detector (53) respectively in a first space (SP1), a second space (SP2), and a third space (SP3) provided in the side part (32). The second step is a step of attaching the side part (32) between the bottom wall (31) and the cover (4) and forming a first cavity (C1) including the first space (SP1), a second cavity (C2) including the second space (SP2), and a third cavity (C3) including the third space (SP3) between the bottom wall (31) and the cover (4). The third step is a step of forming, in the cover (4), at least one first through hole (T1) and at least one second through hole (T2) respectively placing the first cavity (C1) and the second cavity (C2) in communication with an outside. The fifth step is a step of filling each of the at least one first through hole (T1) and the at least one second through hole (T2) with an outgassing material (M1; M2) which is configured to produce a gas. An upper limit value of acceleration detectable by the first acceleration detector (51) is smaller than an upper limit value of acceleration detectable by the second acceleration detector (52). An inner pressure of the first cavity (C1) is higher than an inner pressure of the second cavity (C2). An inner pressure of the third cavity (C3) is lower than the inner pressure of the second cavity (C2). A total opening area of the at least one first through hole (T1) is greater than a total opening area of the at least one second through hole (T2).

With this configuration, the outgassing material (M1; M2) produces the gas, thereby making the inner pressures different. In addition, the total opening area of the at least one first through hole (T1) and the total opening area of the at least one second through hole (T2) are adjusted, thereby adjusting the inner pressures.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

1. A compound sensor comprising:
a package having a first cavity, a second cavity, and a third cavity in an interior of the package;
a first acceleration detector disposed in the first cavity;
a second acceleration detector disposed in the second cavity; and
an angular velocity detector disposed in the third cavity,
an upper limit value of acceleration detectable by the first acceleration detector being smaller than an upper limit value of acceleration detectable by the second acceleration detector,
an inner pressure of the first cavity being higher than an inner pressure of the second cavity,
an inner pressure of the third cavity being lower than the inner pressure of the second cavity.

2. The compound sensor of claim 1, wherein
the package includes a base and a cover,
the base has
a first recess which is at least part of the first cavity, a second recess which is at least part of the second cavity, a third recess which is at least part of the third cavity, and
a first opening, a second opening, and a third opening through which the first recess, the second recess, and the third recess are respectively opened to an outside of the base,
the cover covers the first opening, the second opening, and the third opening,
the cover has at least one first through hole and at least one second through hole respectively placing the first cavity and the second cavity in communication with the outside,
the compound sensor further comprises a getter material which is filled in each of the at least one first through hole and the at least one second through hole and which is configured to adsorb a gas, and
a total opening area of the at least one second through hole is greater than a total opening area of the at least one first through hole.

3. The compound sensor of claim 1, wherein
the package includes a base and a cover,
the base has
a first recess which is at least part of the first cavity, a second recess which is at least part of the second cavity, a third recess which is at least part of the third cavity, and
a first opening, a second opening, and a third opening through which the first recess, the second recess, and the third recess are opened to an outside of the base,
the cover covers the first opening, the second opening, and the third opening,
the cover has at least one first through hole and at least one second through hole respectively placing the first cavity and the second cavity in communication with the outside,
the compound sensor further comprises an outgassing material which is filled in each of the at least one first through hole and the at least one second through hole and which is configured to produce a gas, and
a total opening area of the at least one first through hole is greater than a total opening area of the at least one second through hole.

4. The compound sensor of claim 2, wherein
a number of the at least one second through hole is greater than a number of the at least one first through hole.

5. The compound sensor of claim 3, wherein
a number of the at least one first through hole is greater than a number of the at least one second through hole.

6. The compound sensor of claim 2, wherein
each of the at least one first through hole and the at least one second through hole satisfies a condition that 10≤F/D, where D is a maximum width and F is a depth of each of the at least one first through hole and the at least one second through hole, and D and F are defined for each of the at least one first through hole and the at least one second through hole.

7. The compound sensor of claim 2, wherein
the first acceleration detector includes a movable part configured to be displaced in accordance with acceleration, and
when viewed in a direction in which the base and the cover face each other, the at least one first through hole is provided around a region overlapping the movable part of the first acceleration detector.

8. The compound sensor of claim 2, wherein
the second acceleration detector includes a movable part configured to be displaced in accordance with acceleration, and
when viewed in a direction in which the base and the cover face each other, the at least one second through hole is provided around a region overlapping the movable part of the second acceleration detector.

9. The compound sensor of claim 1, further comprising:
an outgassing material which is disposed in the first cavity and which is configured to produce a gas, and
a getter material which is disposed in the third cavity and which is configured to adsorb a gas.

10. The compound sensor of claim 9, wherein
the outgassing material and the getter material are disposed also in the second cavity.

11. The compound sensor of claim 3, wherein
an atomic percentage “n” of argon atoms in the outgassing material satisfies a condition that 0.1≤n.

12. The compound sensor of claim 3, wherein
an atomic percentage “n” of argon atoms in the outgassing material satisfies a condition that n≤20.

13. A manufacturing method of a compound sensor provided with a package including a bottom wall, a side part, and a cover, the manufacturing method comprising:
a first step of forming a first acceleration detector, a second acceleration detector, and an angular velocity detector respectively in a first space, a second space, and a third space provided in the side part;
a second step of attaching the side part between the bottom wall and the cover and forming a first cavity including the first space, a second cavity including the second space, and a third cavity including the third space between the bottom wall and the cover;
a third step of forming, in the cover, at least one first through hole and at least one second through hole respectively placing the first cavity and the second cavity in communication with an outside; and
a fourth step of, after the second step, filling each of the at least one first through hole and the at least one second through hole with a getter material which is configured to adsorb a gas,
an upper limit value of acceleration detectable by the first acceleration detector being smaller than an upper limit value of acceleration detectable by the second acceleration detector,
an inner pressure of the first cavity being higher than an inner pressure of the second cavity,
an inner pressure of the third cavity being lower than the inner pressure of the second cavity,
a total opening area of the at least one second through hole being greater than a total opening area of the at least one first through hole.

14. A manufacturing method of a compound sensor provided with a package including a bottom wall, a side part, and a cover, the manufacturing method comprising:
a first step of forming a first acceleration detector, a second acceleration detector, and an angular velocity detector respectively in a first space, a second space, and a third space provided in the side part;
a second step of attaching the side part between the bottom wall and the cover and forming a first cavity including the first space, a second cavity including the second space, and a third cavity including the third space between the bottom wall and the cover;
a third step of forming, in the cover, at least one first through hole and at least one second through hole respectively placing the first cavity and the second cavity in communication with an outside; and
a fifth step of filling each of the at least one first through hole and the at least one second through hole with an outgassing material which is configured to produce a gas,
an upper limit value of acceleration detectable by the first acceleration detector being smaller than an upper limit value of acceleration detectable by the second acceleration detector,
an inner pressure of the first cavity being higher than an inner pressure of the second cavity,
an inner pressure of the third cavity being lower than the inner pressure of the second cavity,
a total opening area of the at least one first through hole being greater than a total opening area of the at least one second through hole.
